(19) United States
(12) Patent Application Publication
(10) Pub. No.: US 2024/0028531 A1
(43) Pub. Date: Jan. 25, 2024

(54) DYNAMIC SWITCH FOR MEMORY DEVICES

(71) Applicant: Intel Corporation, Santa Clara, CA (US)

(72) Inventors: John R. DREW, Aloha, OR (US); James A. McCALL, Portland, OR (US); Tongyan ZHAI, Portland, OR (US); Jun LIAO, Portland, OR (US); Min Suet LIM, Gelugor (MY); Shigeki TOMISHIMA, Portland, OR (US)

(21) Appl. No.: 18/375,472

(22) Filed: Sep. 30, 2023

(51) Int. Cl. G06F 13/16; G06F 13/40

(52) U.S. Cl. CPC G06F 13/1694; G06F 13/1689; G06F 13/4022

(57) ABSTRACT

A memory subsystem triggers dynamic switching for memory devices to provide access to active memory devices and prevent access to inactive memory devices. Dynamic switching enables a single bus to switch between multiple memory devices whose capacity otherwise exceeds the capacity of the single bus. A switch can be mounted in a memory module or directly on a motherboard alongside the memory devices. A memory controller can toggle a chip select signal as a single control signal to drive the switch. Each switch includes pairs of field effect transistors (FETs), including any of CMOS, NMOS and PMOS FETs. The switch electrically isolates inactive memory devices to prevent access without the need to electrically short the devices.

### FIELD OF THE INVENTION

This disclosure relates to memory devices and, more particularly, to increasing the capacity of memory devices for high performance systems.

### BACKGROUND OF THE INVENTION

As processors continue to increase in performance and throughput, the exchange of data from memory devices, such as dynamic random access memory devices (DRAMs), to the processor can create a bottleneck in electronics and computing devices. To increase throughput, wider interfaces have been used to increase the number of signal lines used to exchange signals between the memory and the processors. However, more signal lines means more pins on connectors, resulting in larger packages, and more power consumption.

In the case of memory subsystems with memory modules that contain DRAM devices, such as dual inline memory modules (DIMMs) and/or compression attached memory modules (CAMMs), wider memory interfaces become difficult to implement physically. Memory modules typically have constrained connector pin counts, and the use of wider interfaces traditionally requires tradeoffs between how the pin count of the interface will be used. Additionally, wider buses require more logic (e.g., more XOR (exclusive OR) stages) to compute parity for the signals, which can result in higher throughput delays compared to a narrower bus.

The use of double data rate (DDR) memory in which commands and/or data is transferred on both the rising and falling edges of a clock signal, or twice per cycle, addresses some of the foregoing limitations in the width of the memory interface. For example, using only LPDDR (Low Power Double Data Rate) memory in mobile segments is beneficial for power efficiency and form factor. Nevertheless, capacity and performance challenges remain. Future high performance central processor units (CPUs) will require greater memory capacity, including capacity greater than or equal to 128 gigabytes (GB), to meet high performance targets.

### BRIEF DESCRIPTION OF THE DRAWINGS

The described embodiments are illustrated by way of example and not limitation in the figures of the accompanying drawings, in which like references indicate similar elements and in which:

FIG. 1 is an overview and example circuitry of an embodiment of a memory subsystem in which a dynamic switch for memory devices can be implemented.

FIG. 2 is example circuitry of an embodiment of a memory module in which a dynamic switch for memory devices can be implemented.

FIG. 3a is a side view of example circuitry of an embodiment of a memory subsystem in which a dynamic switch for memory devices can be implemented.

FIG. 3b is a plan view of example circuitry of an embodiment of a memory subsystem in which a dynamic switch for memory devices can be implemented.

FIGS. 4a-4c are example circuitry for implementing embodiments of a dynamic switch for memory devices.

FIG. 5 is a flow diagram of certain aspects of a dynamic switch control scheme for implementing embodiments of a dynamic switch for memory devices.

FIGS. 6a-6c are illustrations of eye margins comparing signal integrity between conventional memory subsystems and a memory subsystem in which an embodiment of a dynamic switch for memory devices is implemented.

FIG. 7 is a block diagram of an example memory subsystem in which a dynamic switch for memory devices can be implemented.

FIG. 8 is a block diagram of an example computing system in which a dynamic switch for memory devices can be implemented.

Other features of the described embodiments will be apparent from the accompanying drawings and from the detailed description that follows.

### DETAILED DESCRIPTION

To meet high performance targets for a mobile form factor, memory subsystems require not only high memory capacity of greater than or equal to 128 GB, but also require the capability of maintaining modularity, i.e., using memory modules that are removable. In addition, for a small mobile form factor, support for a Type 3 (T3) mother board is typically required.

One issue in meeting performance targets for such systems using a current low power (LP) double data rate (DDR) modular solution—LPDDR5 memory in an LP compression attached memory module (CAMM)—is that the 128 bit memory bus width has a limitation on capacity of 64 GB with potential expansion to 96 GB, still short of the capacity requirement of greater than or equal to 128 GB for future high performance CPUs.

Another challenge is that expanding to a 258-bit memory bus width is not practical because the memory devices would occupy three sides of the package perimeter in a T3 motherboard, leaving no room for power delivery and other I/Os circuitry.

One alternative is to use a native quad rank (4R) memory solution. However, such a native 4R memory solution requires 16 more pins on the silicon and the package. Moreover, the performance of native 4R memory solution is significantly degraded due to high bus loading. In addition, native 4R DRAM is not supported by the industry due to current form factor limitations of DRAM packages. As a result, most original equipment manufacturers and original design manufacturers of memory systems are willing to trade off memory speed with maximum memory capacity for high performance memory.

In view of the above challenges, given the limitation of the 128 bit memory bus width of current LP modular memory solutions, such as LPCAMM, enabling higher memory capacity is needed to meet the need for high performance memory. Currently, there are LP die density and packaging limitations and no line-of-sight solution for a single LPCAMM to support 128 GB memory capacity.

One major hurdle faced by high performance platforms involves memory capacity scalability to or beyond 128 GB if adopting LPDDR5/5x as the sole or preferred memory technology for mobile solutions. The maximum capacity allowed by a single 2R (dual rank) memory module is at most 96 GB with 24 Gb die density. A 2DPC (two dual memory modules per channel) configuration is known to severely degrade memory bandwidth due to the extra loading and stub effects introduced by such a topology. Likewise, commitment from suppliers to enable 4R (quad rank) LPDDR packages is far from guaranteed.

To meet the above-described challenges, embodiments of a dynamic switch for memory devices implement a new control scheme to schedule dynamic switches DSn to toggle between two sets of memory devices, active memory and inactive memory, where the active and inactive memories (e.g., DRAM devices mounted on the motherboard or mounted in modular low power (LP) compression attached memory modules (CAMMs)) together provide a memory subsystem with as much as double the memory capacity than would otherwise be available while still remaining within a 128-bit memory bus width.

In one embodiment, the dynamic switches DSn can be integrated on new memory modules or on a motherboard alongside the memory devices. Among other advantages, the dynamic switches, DSn, can support a mix of modular memory and soldered-down memory, such as a mix of LPCAMM and LP down, or LPDIMM, UDIMM or SODIMM, in a single design for capacity, modularity, and form factor optimization. In addition, the use of the dynamic switches, DSn, does not involve the cost of adding a new pin on the device silicon. A customer has the flexibility to choose different memory options based on the system capacity requirements.

The following detailed description of the drawings that follow includes non-limiting examples of embodiments of a dynamic switch for memory devices.

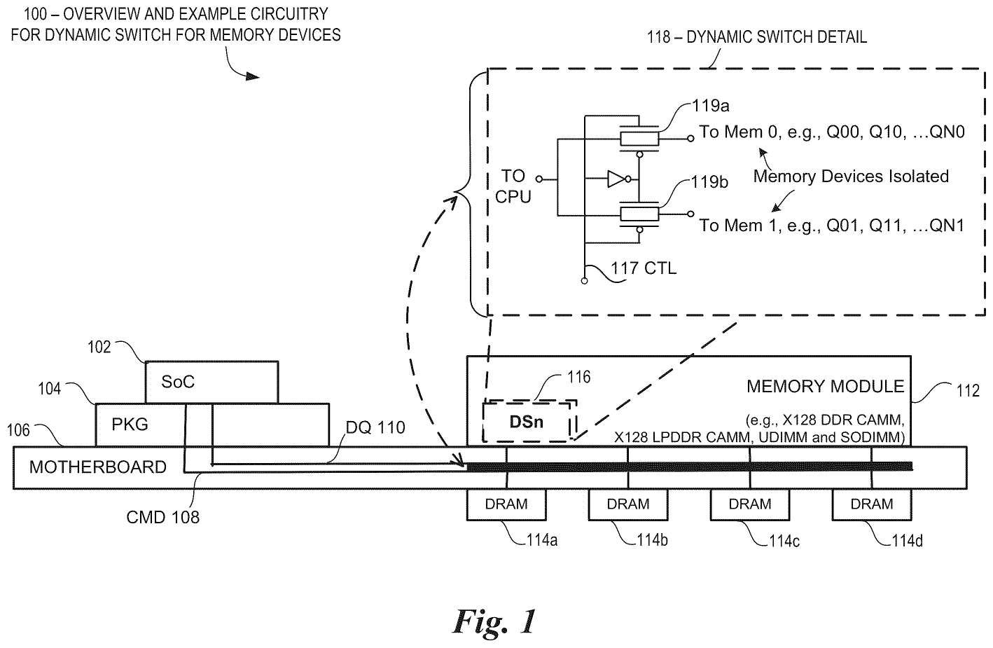

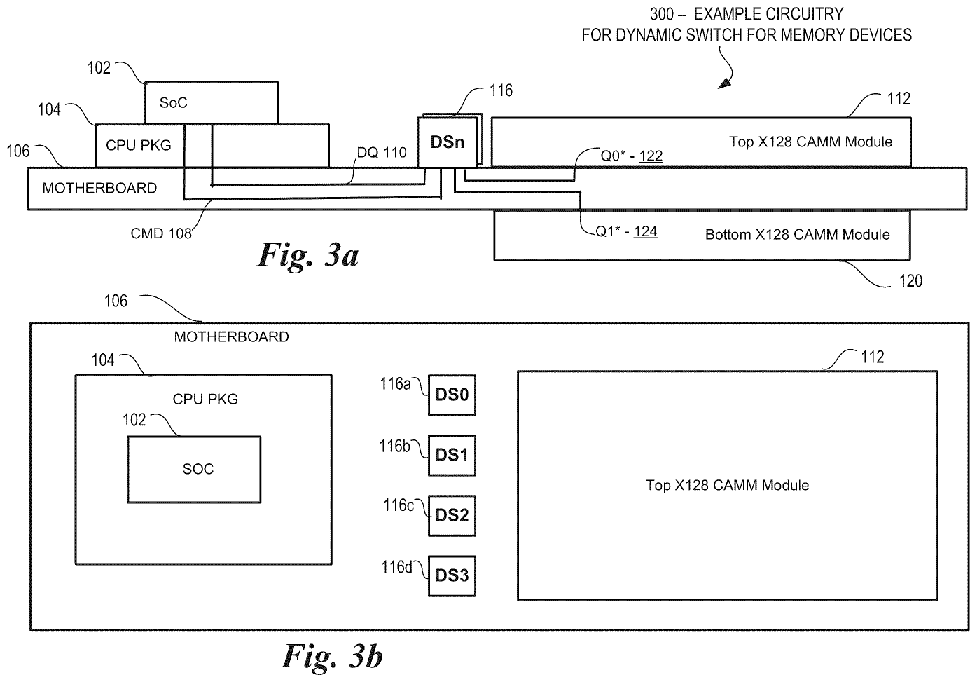

FIG. 1 is an overview and example circuitry of an embodiment of a memory subsystem 100 in which a dynamic switch for memory devices can be implemented. The memory subsystem includes a system on a chip (SoC) 102 mounted on a package 104 and a motherboard 106. A memory module 112 is mounted alongside package 104 on the motherboard 106, and connected via a command address bus CMD 108 and a data signal bus DQ 110. In addition, four non-modular memory devices, DRAM 114a-114d, are mounted to the bottom of the motherboard 106, sharing in the connections CMD 108 and DQ 110. To provide greater memory capacity than the width of the memory bus would normally allow, memory module 112, such as an X128 DDR CAMM memory module, is integrated with one or more dynamic switch circuits DSn 116. In other embodiments, memory module 112 can be a low power (LP) DIMM, an unbuffered DIMM (UDIMM) or a small outline DIMM (SODIMM) in which the dynamic switch circuits DSn 116 have been integrated. (In other embodiments, the dynamic switch circuits DSn 116 can be implemented directly on the motherboard 106 as will be described in further detail with reference to FIGS. 3a-3b, infra.).

As shown in the exploded view of the dynamic switch detail 118 in FIG. 1, in one embodiment, the dynamic switches DSn 116 comprises a set of discrete devices to enable 2DPC (two dual per channel) LPCAMM (low power module memory) and/or Mem-Down (MD) LPDDR5/LPDDR6 (e.g., soldered-down memory, such as DRAM 114a-114d) memory device configurations with minimal impact to the memory bus's operating frequency, i.e., the CMD bus 108 and DQ bus 110. Rather than electrically shorting out memory devices that are not needed during an operation, the dynamic switch 116 electrically isolates inactive memory devices, whether those devices are module memory devices or soldered-down memory. For example, in one embodiment, the DSn 116 comprises one or more small FET (field-effect transistors) pairs 119a, 119b controllable with a single CTL bit signal 117 received from the SoC 102 via the CMD 108. The pair of FETs 119a/119b operate in an XOR on/off scheme controlled by the single CTL bit signal 117. In this manner the pair of FEGs 119a/119b provide a seamless switch between active and inactive memory devices. A memory controller typically controls the single CTL bit signal 117 by toggling a chip select (CS) signal.

In one embodiment, the CTL bit signal 117 drives the one or more FET pairs 119a/119b to switch between two sets of memory, active memory and inactive memory, here illustrated as Mem 0 memory and Mem 1 memory. Mem 0 memory, e.g., Q00, Q10, . . . QN0 is electrically isolated from Mem 1 memory, e.g., Q01, Q11, . . . QN1 such that only one set of memory is actively receiving data signals DQ 110 at any given point in time. This allows the memory subsystem 100 to stay within the memory bus limitation of 128-bits while providing memory resources that potentially double the 128 GB capacity.

In one embodiment, the DSn 116 serves as a light-weight MUX (multiplexor circuit) allowing for a single bus to communicate with multiple modules or ICs (integrated circuits) without the need to electrically short these devices as is done with prior-art techniques. As such, many of the disadvantages of 2DPC (two dual per channel) platforms are resolved since both the capacitive loading and the stub effects of the inactive module/device are electrically isolated from the target by an off-state FET pair.

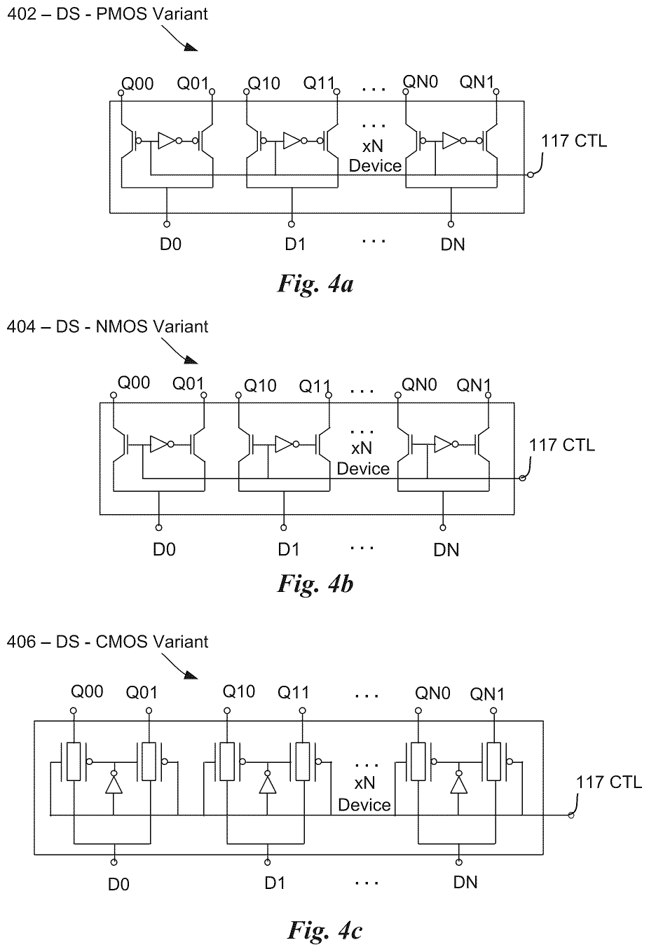

The operation of the one or more FET pairs 119a/119b that comprise the dynamic switches DSn 116 can vary based on the type of FET in use. In the illustrated embodiment, one type of the one or more FET pairs 119a/119b comprise a complementary metal-oxide-semiconductor (CMOS) circuit as further described with reference to FIG. 4c, supra. Other types of FET pairs 119a/119b can be employed, depending on the overall voltage used in the memory subsystem 100. For example, as illustrated in FIG. 4a, infra., a p-channel metal-oxide-semiconductor (PMOS) can be employed. Alternatively, as illustrated in FIG. 4b, infra, an n-channel metal-oxide-semiconductor (NMOS) can be employed.

In one embodiment, regardless of how the FET pairs 119a/119b vary in composition, the dynamic switch circuits DS0-DS3, 116a-116d are driven by the CTL bit signal 117 to provide or prevent access, at least temporarily, by electrically isolating the inactive DRAM. The DRAM that can be electrically isolated includes any DRAM co-located with the dynamic switch circuits DS0-DS3 in a memory module 112 or co-located with any DRAM 114a, 114b, 114c and 114d attached to the motherboard 106, an example of which is shown infra., in FIGS. 3a-3b.

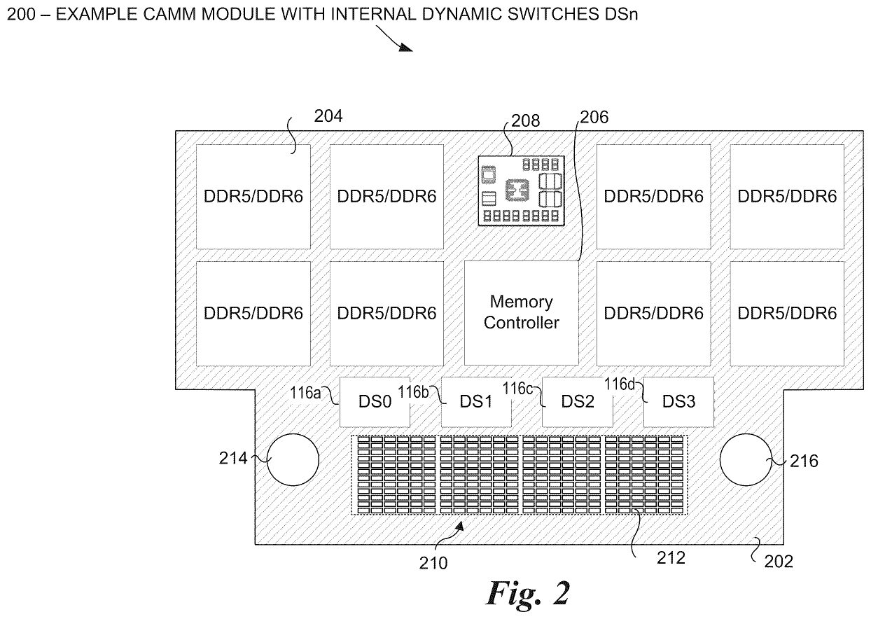

FIG. 2 is example circuitry of an embodiment of a memory module 200 in which a dynamic switch for memory devices can be implemented. In this example, the memory module 200 is a CAMM, but in other embodiments, other types of modular memory could be used in a similar manner, such as an LPDIMM, UDIMM and SODIMM module. As shown, circuitry for multiple dynamic switches DS0 116a, DS1 116b, DS2 116c and DS3 116d, are included alongside a combination of DDR memory chips.

In one embodiment the DDR memory CAMM 200 includes a substrate 202 to which multiple chips or package are mounted alongside the dynamic switch circuits DS0-DS3, 116a-116d, as illustrated by DDR5/DDR6 chips or packages 204 and a memory controller 206. DDR memory CAMM 200 also includes VR circuitry 208, as well as other circuitry and components (not shown). One or more arrays 210 of compression attachment pads 212 are formed toward the bottom of substrate 202. In addition, a pair of holes 214 and 216 are formed in substrate 202 to facilitate the fasteners that secure the CAMM.

In operation, the CAMM 200 permits the dynamic switch circuits DS0-DS3, 116a-116d, to access the CTL bit signal 117 provided by the CMD bus 108 and the data signals provided by the DQ bus 110 to provide or prevent access to the active/inactive DDR5/DDR6 chips 204 as needed. In one embodiment the dynamic switch circuits DS0-DS3, 116a-116d are driven by the CTL bit signal 117 to provide or prevent access, at least temporarily, by electrically isolating the inactive DDR5/DDR6 chips 204 as needed.

FIG. 3a is a side view of example circuitry of an embodiment of a memory subsystem 300 in which a dynamic switch for memory devices can be implemented. FIG. 3b is a plan view of example circuitry of an embodiment of the memory subsystem 300 in which a dynamic switch for memory devices can be implemented.

FIGS. 3a-3b illustrate that several DSn, DS0 116a, DS1 116b, DS2 116c and DS3 116d, can be used to accommodate an entire memory bus. As shown, the dynamic switches 116 can be placed directly on the motherboard 108 near whichever memory solution is employed, such as the pair of top and bottom X128 CAMM modules 112/120, referred to as a CAMM-on-CAMM configuration. As such, the dynamic switches DSn 116 can be easily identified. In operation, the dynamic switches DSn 116 control access to the memory devices (not shown) contained in the modules 112/120 such that the memory devices, when active in the top-mounted module 112, only the QN0 signal paths Q0* 122 are open. Likewise, for the memory devices, when active in the bottom-mounted module 120, only the QN1 signal paths Q1* 124 are open.

In one embodiment, in addition to the CAMM-on-CAMM configuration shown in FIGS. 3a-3b, there are likely other scenarios in which a combination of CAMM (or other types of modular memory, e.g., DIMM) and solder-down memory (e.g., the DRAM 114a, 114b, 114c and 114d of FIG. 1) will be desirable to the customer. Configurations employing different types of memory, i.e., modular and solder-down memory, can be managed using DSn dynamic switches 116 deployed alongside the memory. For example, the DSn dynamic switches 116 can be co-located on the motherboard with any memory module 112 attached to the motherboard 106. In addition, the different types of memory managed using DSn dynamic switches 116, i.e., modular and solder-down memory, can be mounted in different configurations, such as the top-mounted/bottom-mounted configuration shown in FIG. 3a, as well as mounted side-by-side (not shown) or stacked on a same side (not shown). Since the DSn dynamic switch devices 116 comprise only a pair of FETs per data signal, DQ, the size of each dynamic switch circuit of DSn 116 is much smaller compared to the size of adding a DQ pin pitch. Importantly, the routing of memory traces will not be impacted by the usage of DSn 116 dynamic switches to control access to the memory.

FIGS. 4a-4c are example circuitry for implementing embodiments of a dynamic switch for memory devices. As illustrated, several of the FET pairs 119a/119b that comprise a dynamic switch DSn, such as DSn 116, can be placed on a discrete device, or integrated circuit (IC). In each of the embodiments illustrated in FIGS. 4a-4c, as many as twelve (12) FET pairs corresponding to the signals that are received in the memory devices can be provided, including 8 DQ bits, one DQS pair and one WCK pair for dynamic switches for an LPDDR5/5x memory scenario.

As shown in each of the variants, 402, 404 and 406, embodiments of a dynamic switch for memory devices includes several combinations of MOS (metal-oxide-semiconductor) devices. The FET pairs 119a/119b share a single control signal CTL 117. The FET pairs 119a/119b function as a voltage-controlled switch based on the single control signal CTL 117. For example, the single control signal CTL 117 drives the FET pairs to turn on or off depending on whether the control signal voltage on it is either high or low.

In one embodiment, the NMOS variant (n-channel MOS) shown in FIG. 4b will likely be most suitable for LPDDR5/5x configurations whose bus voltage will not meaningfully exceed 0.4V. On the other hand, the PMOS (p-channel MOS) variant shown in FIG. 4a will likely be most suitable for DDR5 applications whose bus voltage lies within the 0.5V-1.1V window.

In one embodiment, the CMOS (Complementary MOS) variant as shown in FIG. 4c (and as illustrated in the example circuitry in FIG. 1) may be used as a cost-reduction choice given its lack of a required inverter for applications insensitive to NMOS/PMOS mismatch between the Q00/Q01 output paths.

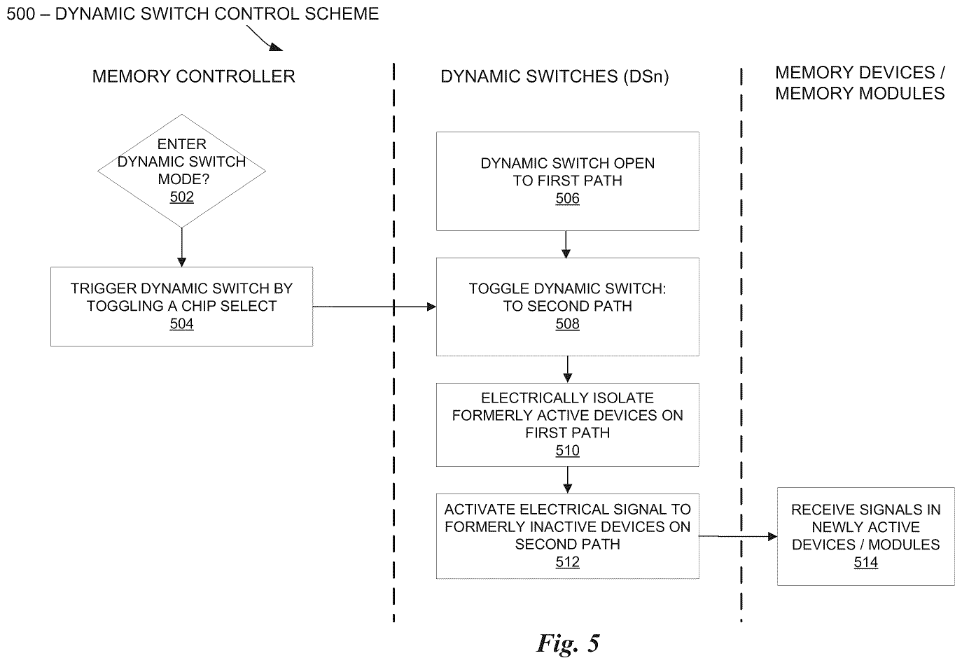

FIG. 5 is a flow diagram of certain aspects of a dynamic switch control scheme 500 for implementing embodiments of a dynamic switch for memory devices. Process 500 provides an example of entering a dynamic switch mode of operation based on command encoding. In one embodiment, the memory controller determines to place a set of memory devices or DRAM, including, in some cases, a memory module, in an inactive state or an active state. In one embodiment, at 504, the memory controller triggers one or more dynamic switch(es) DSn by toggling a chip select (CS) signal. In one embodiment, a logic transition of the CS signal line is to trigger one or more dynamic switches DSn 116 when the memory controller is aware of the presence of dynamic switch controlled memory 502. In one embodiment, the CS signal comprises the single CTL bit signal 117 received in the DSn 116 from the SOC 102 via the CMD 108.

In one embodiment, at 506 the dynamic switches DSn 116 may be currently open to a first signal path. In response to toggling the CS signal, the dynamic switches DSn toggle to a second signal path 508. As a result, at 510 the dynamic switches DSn electrically isolate formerly active memory devices on the first path, and at 512 activate electrical signals to formerly inactive devices on the second path. At 514, the memory devices and/or memory modules controlled by the dynamic switches DSn 116 receive (and send) signals in the newly active memory devices/modules.

In one embodiment, the process 500 repeats as needed to alternate access to memories that are active versus inactive on account of toggling the dynamic switches DSn.

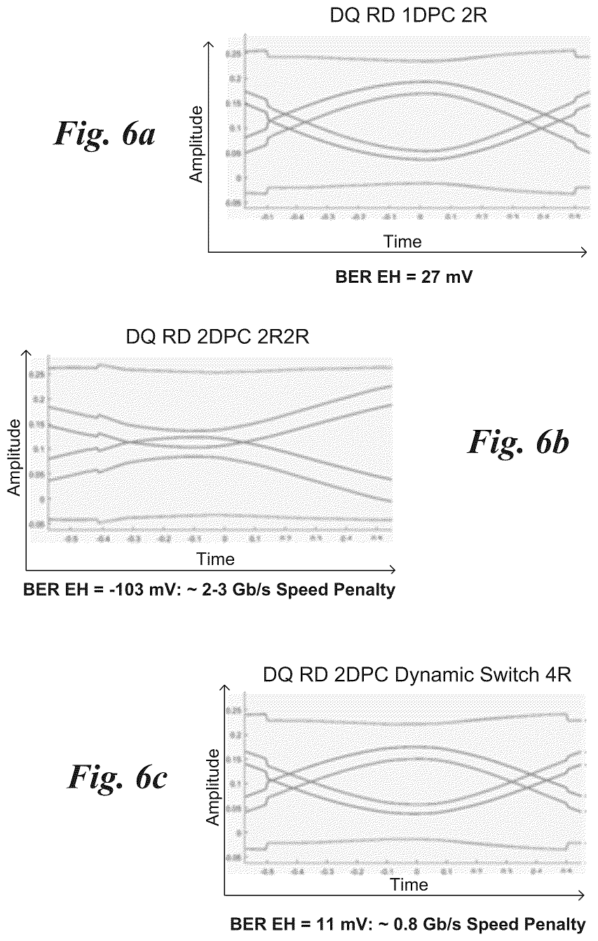

FIGS. 6a-6c are illustrations of eye margins comparing signal integrity between conventional memory subsystems and a memory subsystem in which an embodiment of a dynamic switch for memory devices is implemented. Notably, pathfinding simulations indicate that embodiments of dynamic switches for memory devices to increase capacity is a significantly more favorable solution to increasing memory capacity than the traditional solution of shorting two memory modules in a bottom/top configuration.

For example, FIG. 6a shows example eye margins for a traditional, one per channel 1DPC dual rank 2R memory subsystem. As shown, the bit error rate (BER) is approximately 27 mV. FIG. 6b shows example eye margins for a two per channel 2DPC 2R2R memory subsystem. As shown, the BER in FIG. 6b is estimated at −103 mV, approximately a 2-3 Gb/s Speed Penalty.

In contrast, FIG. 6c shows example eye margins for a two per channel 2DPC quad rank 4R memory subsystem in which dynamic switching has been implemented in accordance with an embodiment. As shown, the BER in FIG. 6c is estimated at 11 mV, approximately 0.8 Gb/s Speed Penalty. While some signal degradation is observed (and expected) in the dynamic switch configuration shown in FIG. 6c, it is significantly less than the signal degradation shown in the 1DPC dual rank 2R memory subsystem in FIG. 6a. Likewise, the dynamic switching signal degradation is less than the signal degradation shown in the 2DPC 2R2R configuration in FIG. 6b. If anything, a 2DPC 4R memory subsystem in which an embodiment of dynamic switching has been implemented demonstrates, as illustrated in FIG. 6c, a few speed bins advantage (0.0.8 Gb/s versus 2-3 Gb/s) over the traditional native 2DPC 2R2R configuration in FIG. 6b.

One potential conflict with implementing embodiments of dynamic switching for memory devices is the potential to conflict with other memory subsystem operations that depend on timing, (i.e. the time required for the CTL bit to switch from one output to another), such as rank-switch timing. In the context of DDR memory solutions, however, a single rank of memory is only ever used for a particular burst. As a result, there is no scenario in which the dynamic switches will need to switch ranks within the scope of a single data unit interval (UI). For LPDDR5, the rank to rank switch is limited by on die termination (ODT) turn on time. As shown in the Joint Electron Device Engineering Council (JEDEC) LPDDR specification (Table 258 from JEDEC LPDDR Standard No. 209-5B, p. 347, published June 2021), the minimum ODT turn on time is 1.5 ns (nanosecond). This is a sufficient amount of time to complete the low cost FET switching performed in embodiments of the dynamic switches described herein. Even in a constrained scenario, the FET pairs 119 comprising embodiments of the dynamic switches DSn 116 described herein will likely have at least 1500 ps (picoseconds) to switch between active and inactive memory devices. In one embodiment, 1500 ps is achievable if the dynamic switches DSn 116 are manufactured using a reasonably modern silicon process.

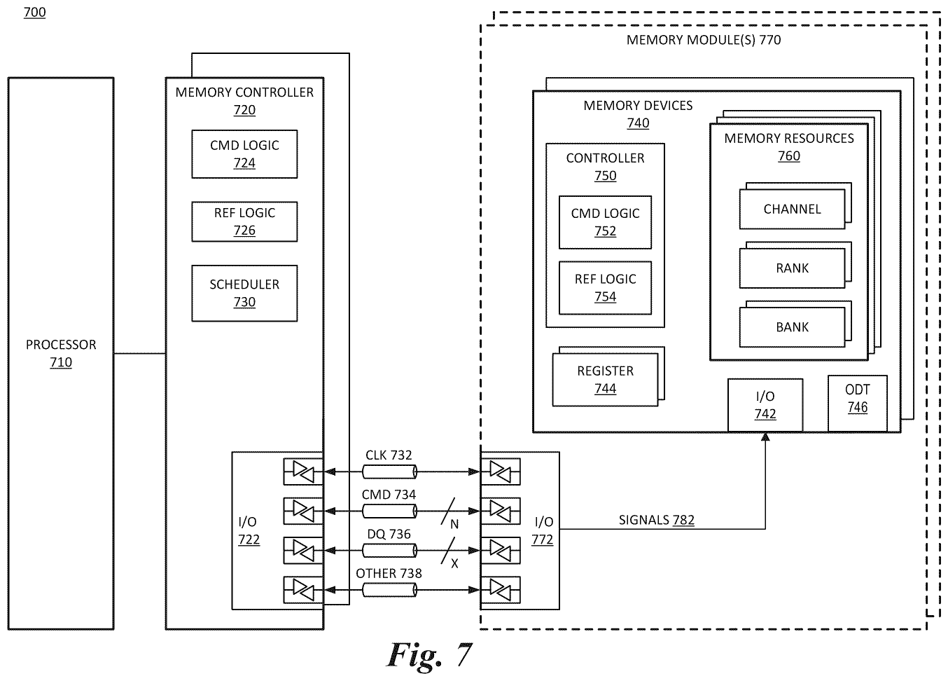

FIG. 7 is a block diagram of an example memory subsystem in which a dynamic switch for memory devices can be implemented. System 700 includes a processor and elements of a memory subsystem in a computing device. Processor 710 represents a processing unit of a computing platform that may execute an operating system (OS) and applications, which can collectively be referred to as the host or the user of the memory. The OS and applications execute operations that result in memory accesses. Processor 710 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 700 can be implemented as SoC (system on a chip), or be implemented with standalone components.

While various embodiments described herein use the term “system-on-a-chip” or System-on-Chip (“SoC”) to describe a device or system having a processor and associated circuitry (e.g., Input/Output (“I/O”) circuitry, power delivery circuitry, memory circuitry, etc.) integrated monolithically into a single Integrated Circuit (“IC”) die, or chip, the present disclosure is not limited in that respect. For example, in various embodiments of the present disclosure, a device or system can have one or more processors (e.g., one or more processor cores) and associated circuitry (e.g., Input/Output (“I/O”) circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems the various dies, tiles and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random access memory), or some variant such as synchronous DRAM (SDRAM).

Various types of memory may be used in the LP memory and DDR memory modules described and illustrated herein, including standardized memory devices (e.g., chips and/or packages). Such standards include DDR4 (Double Data Rate version 4, initial specification published in September 2012 by JEDEC (Joint Electronic Device Engineering Council). DDR4E (DDR version 4), LPDDR3 (Low Power DDR version 3, JESD209-3B, August 2013 by JEDEC), LPDDR4 (LPDDR version 4, JESD209-4, originally published by JEDEC in August 2014), WIO2 (Wide Input/Output version 2, JESD229-2 originally published by JEDEC in August 2014, HBM (High Bandwidth Memory, JESD325, originally published by JEDEC in October 2013), DDR5 (DDR version 5, JESD79-5A, published October, 2021), DDR version 6 (currently under draft development), LPDDR5, HBM2E, HBM3, and HBM-PIM, or others or combinations of memory technologies, and technologies based on derivatives or extensions of such specifications. The JEDEC standards are available at www.jedec.org.

In addition to, or alternatively to, volatile memory, in one embodiment, reference to memory devices can refer to a nonvolatile memory device whose state is determinate even if power is interrupted to the device. In one embodiment, the nonvolatile memory device is a block addressable memory device, such as NAND or NOR technologies. Thus, a memory device can also include a future generation nonvolatile devices, such as a three dimensional crosspoint memory device, other byte addressable nonvolatile memory devices, or memory devices that use chalcogenide phase change material (e.g., chalcogenide glass). In one embodiment, the memory device can be or include multi-threshold level NAND flash memory, NOR flash memory, single or multi-level phase change memory (PCM) or phase change memory with a switch (PCMS), a resistive memory, nanowire memory, ferroelectric transistor random access memory (FeTRAIVI), magnetoresistive random access memory (MRAM) memory that incorporates memristor technology, or spin transfer torque (STT)-MRAM, or a combination of any of the above, or other memory.

Descriptions herein referring to a “RAM” or “RAM device” can apply to any memory device that allows random access, whether volatile or nonvolatile. Descriptions referring to a “DRAM” or a “DRAM device” can refer to a volatile random access memory device. The memory device or DRAM can refer to the die itself, to a packaged memory product that includes one or more dies, or both. In one embodiment, a system with volatile memory that needs to be refreshed can also include nonvolatile memory.

Memory controller 720 represents one or more memory controller circuits or devices for system 700. Memory controller 720 represents control logic that generates memory access commands in response to the execution of operations by processor 710. Memory controller 720 accesses one or more memory devices 740. Memory devices 740 can be DRAM devices in accordance with any referred to above. In one embodiment, memory devices 740 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one embodiment, settings for each channel are controlled by separate mode registers or other register settings. In one embodiment, each memory controller 720 manages a separate memory channel, although system 700 can be configured to have multiple channels managed by a single controller, or to have multiple controllers on a single channel. In one embodiment, memory controller 720 is part of host processor 710, such as logic implemented on the same die or implemented in the same package space as the processor.

Memory controller 720 includes I/O interface logic 722 to couple to a memory bus, such as a memory channel as referred to above. I/O interface logic 722, corresponding I/O interface logic 772 (as well as I/O interface logic 742 of memory device 740) can include pins, pads, connectors, signal lines, traces, or wires, or other hardware to connect the devices, or a combination of these. I/O interface logic 722 can include a hardware interface. As illustrated, I/O interface logic 722 includes at least drivers/transceivers for signal lines. Commonly, wires within an integrated circuit interface couple with a pad, pin, or connector to interface signal lines or traces or other wires between devices. I/O interface logic 722 can include drivers, receivers, transceivers, or termination, or other circuitry or combinations of circuitry to exchange signals 782 on the signal lines between the devices. The exchange of signals 782 includes at least one of transmit or receive. While shown as coupling I/O 722 from memory controller 720 to I/O 742 of memory device 740, it will be understood that in an implementation of system 700 where groups of memory devices 740 are accessed in parallel, multiple memory devices can include I/O interfaces to the same interface of memory controller 720. In an implementation of system 700 including one or more memory modules 770, I/O 742 can include interface hardware of the memory module in addition to interface hardware on the memory device itself. Other memory controllers 720 will include separate interfaces to other memory devices 740.

The bus between memory controller 720 and memory devices 740 can be implemented as multiple signal lines 782 coupling memory controller 720 to memory devices 740. The bus may typically include at least clock (CLK) 732, command/address (CMD) 734, and write data (DQ) and read data (DQ) 736, and zero or more other signal lines 738. In one embodiment, a bus or connection between memory controller 720 and memory can be referred to as a memory bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one embodiment, independent channels have different clock signals, C/A buses, data buses, and other signal lines. Thus, system 700 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 720 and memory devices 740. An example of serial bus technology is 8B10B encoding and transmission of high-speed data with embedded clock over a single differential pair of signals in each direction. In one embodiment, CMD 734 represents signal lines shared in parallel with multiple memory devices. In one embodiment, multiple memory devices share encoding command signal lines of CMD 734, and each has a separate chip select (CS_n) signal line to select individual memory devices.

It will be understood that in the example of system 700, the bus between memory controller 720 and memory devices 740 includes a subsidiary command bus CMD 734 and a subsidiary bus to carry the write and read data, DQ 736. In one embodiment, the data bus can include bidirectional lines for read data and for write/command data. In another embodiment, the subsidiary bus DQ 736 can include unidirectional write signal lines for write and data from the host to memory, and can include unidirectional lines for read data from the memory to the host. In accordance with the chosen memory technology and system design, other signals 738 may accompany a bus or sub bus, such as strobe lines DQS. Based on design of system 700, or implementation if a design supports multiple implementations, the data bus can have more or less bandwidth per memory device 740. For example, the data bus can support memory devices that have either a x32 interface, a x16 interface, a x8 interface, or other interface. The convention “xW,” where W is an integer that refers to an interface size or width of the interface of memory device 740, which represents a number of signal lines to exchange data with memory controller 720. The interface size of the memory devices is a controlling factor on how many memory devices can be used concurrently per channel in system 700 or coupled in parallel to the same signal lines. In one embodiment, high bandwidth memory devices, wide interface devices, or stacked memory configurations, or combinations, can enable wider interfaces, such as a x128 interface, a x256 interface, a x512 interface, a x1024 interface, or other data bus interface width.

In one embodiment, memory devices 740 and memory controller 720 exchange data over the data bus in a burst, or a sequence of consecutive data transfers. The burst corresponds to a number of transfer cycles, which is related to a bus frequency. In one embodiment, the transfer cycle can be a whole clock cycle for transfers occurring on a same clock or strobe signal edge (e.g., on the rising edge). In one embodiment, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length 8 (BL8), and each memory device 740 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 740 represent memory resources for system 700. In one embodiment, each memory device 740 is a separate memory die. In one embodiment, each memory device 740 can interface with multiple (e.g., 2) channels per device or die. Each memory device 740 includes I/O interface logic 742, which has a bandwidth determined by the implementation of the device (e.g., x16 or x8 or some other interface bandwidth). I/O interface logic 742 enables the memory devices to interface with memory controller 720. I/O interface logic 742 can include a hardware interface, and can be in accordance with I/O 722 of memory controller, but at the memory device end. In one embodiment, multiple memory devices 740 are connected in parallel to the same command and data buses. In another embodiment, multiple memory devices 740 are connected in parallel to the same command bus, and are connected to different data buses. For example, system 700 can be configured with multiple memory devices 740 coupled in parallel, with each memory device responding to a command, and accessing memory resources 760 internal to each. For a Write operation, an individual memory device 740 can write a portion of the overall data word, and for a Read operation, an individual memory device 740 can fetch a portion of the overall data word. As non-limiting examples, a specific memory device can provide or receive, respectively, 8 bits of a 128-bit data word for a Read or Write transaction, or 8 bits or 16 bits (depending for a x8 or a x16 device) of a 256-bit data word. The remaining bits of the word will be provided or received by other memory devices in parallel.

In one embodiment, memory devices 740 are disposed directly on a motherboard or host system platform (e.g., a PCB (printed circuit board) on which processor 710 is disposed) of a computing device. In one embodiment, memory devices 740 can be organized into memory modules 770. In one embodiment, memory modules 770 represent dual inline memory modules (DIMMs). In one embodiment, memory modules 770 represent compression attached memory modules (CAMMs). In one embodiment, memory modules 770 represent other organization of multiple memory devices to share at least a portion of access or control circuitry, which can be a separate circuit, a separate device, or a separate board from the host system platform. Memory modules 770 can include multiple memory devices 740, and the memory modules can include support for multiple separate channels to the included memory devices disposed on them. In another embodiment, memory devices 740 may be incorporated into the same package as memory controller 720, such as by techniques such as multi-chip-module (MCM), package-on-package, through-silicon via (TSV), or other techniques or combinations. Similarly, in one embodiment, multiple memory devices 740 may be incorporated into memory modules 770, which themselves may be incorporated into the same package as memory controller 720. It will be appreciated that for these and other embodiments, memory controller 720 may be part of host processor 710.

Memory devices 740 each include memory resources 760. Memory resources 760 represent individual arrays of memory locations or storage locations for data. Typically memory resources 760 are managed as rows of data, accessed via wordline (rows) and bitline (individual bits within a row) control. Memory resources 760 can be organized as separate channels, ranks, and banks of memory. Channels may refer to independent control paths to storage locations within memory devices 740. Ranks may refer to common locations across multiple memory devices (e.g., same row addresses within different devices). Banks may refer to arrays of memory locations within a memory device 740. In one embodiment, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one embodiment, memory devices 740 include one or more registers 744. Register 744 represents one or more storage devices or storage locations that provide configuration or settings for the operation of the memory device. In one embodiment, register 744 can provide a storage location for memory device 740 to store data for access by memory controller 720 as part of a control or management operation. In one embodiment, register 744 includes one or more Mode Registers. In one embodiment, register 744 includes one or more multipurpose registers. The configuration of locations within register 744 can configure memory device 740 to operate in different “modes,” where command information can trigger different operations within memory device 740 based on the mode. Additionally or in the alternative, different modes can also trigger different operation from address information or other signal lines depending on the mode. Settings of register 744 can indicate configuration for I/O settings (e.g., timing, termination or ODT (on-die termination) 746, driver configuration, or other I/O settings).

In one embodiment, memory device 740 includes ODT 746 as part of the interface hardware associated with I/O 742. ODT 746 can be configured as mentioned above, and provide settings for impedance to be applied to the interface to specified signal lines. In one embodiment, ODT 746 is applied to DQ signal lines. In one embodiment, ODT 746 is applied to command signal lines. In one embodiment, ODT 746 is applied to address signal lines. In one embodiment, ODT 746 can be applied to any combination of the preceding. The ODT settings can be changed based on whether a memory device is a selected target of an access operation or a non-target device. ODT 746 settings can affect the timing and reflections of signaling on the terminated lines. Careful control over ODT 746 can enable higher-speed operation with improved matching of applied impedance and loading. ODT 746 can be applied to specific signal lines of I/O interface 742, 722, and is not necessarily applied to all signal lines.

Memory device 740 includes controller 750, which represents control logic within the memory device to control internal operations within the memory device. For example, controller 750 decodes commands sent by memory controller 720 and generates internal operations to execute or satisfy the commands. Controller 750 can be referred to as an internal controller, and is separate from memory controller 720 of the host. Controller 750 can determine what mode is selected based on register 744, and configure the internal execution of operations for access to memory resources 760 or other operations based on the selected mode. Controller 750 generates control signals to control the routing of bits within memory device 740 to provide a proper interface for the selected mode and direct a command to the proper memory locations or addresses. Controller 750 includes command logic 752, which can decode command encoding received on command and address signal lines. Thus, command logic 752 can be or include a command decoder. With command logic 752, memory device can identify commands and generate internal operations to execute requested commands.

Referring again to memory controller 720, memory controller 720 includes command (CMD) logic 724, which represents logic or circuitry to generate commands to send to memory devices 740. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 740, memory controller 720 can issue commands via I/O 722 to cause memory device 740 to execute the commands. In one embodiment, controller 750 of memory device 740 receives and decodes command and address information received via I/O 742 from memory controller 720. Based on the received command and address information, controller 750 can control the timing of operations of the logic and circuitry within memory device 740 to execute the commands. Controller 750 is responsible for compliance with standards or specifications within memory device 740, such as timing and signaling requirements. Memory controller 720 can implement compliance with standards or specifications by access scheduling and control.

Memory controller 720 includes scheduler 730, which represents logic or circuitry to generate and order transactions to send to memory device 740. From one perspective, the primary function of memory controller 720 could be said to schedule memory access and other transactions to memory device 740. Such scheduling can include generating the transactions themselves to implement the requests for data by processor 710 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 720 typically includes logic such as scheduler 730 to allow selection and ordering of transactions to improve performance of system 700. Thus, memory controller 720 can select which of the outstanding transactions should be sent to memory device 740 in which order, which is typically achieved with logic much more complex than a simple first-in first-out algorithm. Memory controller 720 manages the transmission of the transactions to memory device 740, and manages the timing associated with the transaction. In one embodiment, transactions have deterministic timing, which can be managed by memory controller 720 and used in determining how to schedule the transactions with scheduler 730.

In one embodiment, memory controller 720 includes refresh (REF) logic 726. Refresh logic 726 can be used for memory resources that are volatile and need to be refreshed to retain a deterministic state. In one embodiment, refresh logic 726 indicates a location for refresh, and a type of refresh to perform. Refresh logic 726 can trigger self-refresh within memory device 740, or execute external refreshes which can be referred to as auto refresh commands) by sending refresh commands, or a combination. In one embodiment, system 700 supports all bank refreshes as well as per bank refreshes. All bank refreshes cause the refreshing of banks within all memory devices 740 coupled in parallel. Per bank refreshes cause the refreshing of a specified bank within a specified memory device 740. In one embodiment, controller 750 within memory device 740 includes refresh logic 754 to apply refresh within memory device 740. In one embodiment, refresh logic 754 generates internal operations to perform refresh in accordance with an external refresh received from memory controller 720. Refresh logic 754 can determine if a refresh is directed to memory device 740, and what memory resources 760 to refresh in response to the command.

In one embodiment, chip select (CS) is considered part of command bus CMD 734. In one embodiment, CS can be considered separate from the other command signals, as part of other signals 738. In either case, the CS signal provides control functions to circuitry such as embodiments of dynamic switches for memory devices as described herein. The circuitry can include signal routing and operational logic. In one embodiment a logic transition of the CS signal line is to trigger one or more dynamic switches DSn 116 for memory devices as described herein.

In one embodiment, a CS pin refers to a connector provided for external chip select signaling in a device “pinout”. Traditionally CS has a function of identifying a memory device for a command operation. In one embodiment, memory controller 720 triggers entry into dynamic switching for memory devices by asserting the CS signal. In one embodiment, memory controller 720 drives a logic high on the CS signal line to assert CS. In one embodiment, memory controller 720 drives a logic low on the CS signal line to assert CS (e.g., for an inverted signal). As needed, memory controller 720 can provide proper encoding on the command signal lines at the rising edge of the clock in conjunction with asserting the CS signal.

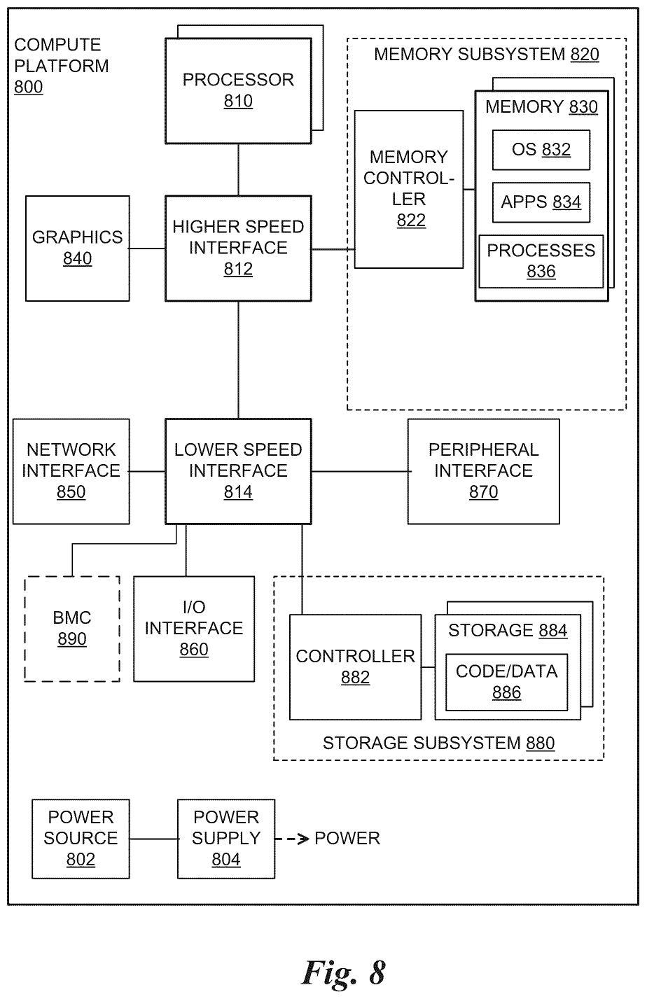

FIG. 8 is a block diagram of an example computing system in which a dynamic switch for memory devices can be implemented. Compute platform 800 represents a computing device or computing system in accordance with any example described herein, and can be a server, laptop computer, desktop computer, or the like. More generally, compute platform 800 is representative of any type of computing device or system employing one or more application specific integrated circuits (ASICs).

Compute platform 800 includes a processor 810, which provides processing, operation management, and execution of instructions for compute platform 800. Processor 810 can include any type of microprocessor, central processing unit (CPU), graphics processing unit (GPU), processing core, or other processing hardware to provide processing for compute platform 800, or a combination of processors. Processor 810 controls the overall operation of compute platform 800, and can be or include, one or more programmable general-purpose or special-purpose microprocessors, digital signal processors (DSPs), programmable controllers, ASICs, programmable logic devices (PLDs), or the like, or a combination of such devices.

In one example, compute platform 800 includes interface 812 coupled to processor 810, which can represent a higher speed interface or a high throughput interface for system components that needs higher bandwidth connections, such as memory subsystem 820 or graphics interface components 840. Interface 812 represents an interface circuit, which can be a standalone component or integrated onto a processor die. Where present, graphics interface 840 interfaces to graphics components for providing a visual display to a user of compute platform 800. In one example, graphics interface 840 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 840 generates a display based on data stored in memory 830 or based on operations executed by processor 810 or both.

Memory subsystem 820 represents the main memory of compute platform 800 and provides storage for code to be executed by processor 810, or data values to be used in executing a routine. Memory 830 of memory subsystem 820 may include one or more memory devices such as DRAM DIMMs, CAMMs, read-only memory (ROM), flash memory, or other memory devices, or a combination of such devices. Memory 830 stores and hosts, among other things, operating system (OS) 832 to provide a software platform for execution of instructions in compute platform 800. Additionally, applications 834 can execute on the software platform of OS 832 from memory 830. Applications 834 represent programs that have their own operational logic to perform execution of one or more functions. Processes 836 represent agents or routines that provide auxiliary functions to OS 832 or one or more applications 834 or a combination. OS 832, applications 834, and processes 836 provide software logic to provide functions for compute platform 800. In one example, memory subsystem 820 includes memory controller 822, which is a memory controller to generate and issue commands to memory 830. It will be understood that memory controller 822 could be a physical part of processor 810 or a physical part of interface 812. For example, memory controller 822 can be an integrated memory controller, integrated onto a circuit with processor 810.

While not specifically illustrated, it will be understood that compute platform 800 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus.

In one example, compute platform 800 includes interface 814, which can be coupled to interface 812. Interface 814 can be a lower speed interface than interface 812. In one example, interface 814 represents an interface circuit, which can include standalone components and integrated circuitry. In one example, multiple user interface components or peripheral components, or both, couple to interface 814. Network interface 850 provides compute platform 800 with the ability to communicate with remote devices (e.g., servers or other computing devices) over one or more networks. Network interface 850 can include an Ethernet adapter, wireless interconnection components, cellular network interconnection components, USB (universal serial bus), or other wired or wireless standards-based or proprietary interfaces. Network interface 850 can exchange data with a remote device, which can include sending data stored in memory or receiving data to be stored in memory.

In one example, compute platform 800 includes one or more I/O interface(s) 860. I/O interface(s) 860 can include one or more interface components through which a user interacts with compute platform 800 (e.g., audio, alphanumeric, tactile/touch, or other interfacing). Peripheral interface 870 can include any hardware interface not specifically mentioned above. Peripherals refer generally to devices that connect dependently to compute platform 800. A dependent connection is one where compute platform 800 provides the software platform or hardware platform or both on which operation executes, and with which a user interacts.

In one example, compute platform 800 includes storage subsystem 880 to store data in a nonvolatile manner. In one example, in certain system implementations, at least certain components of storage subsystem 880 can overlap with components of memory subsystem 820. Storage subsystem 880 includes storage device(s) 884, which can be or include any conventional medium for storing large amounts of data in a nonvolatile manner, such as one or more magnetic, solid state, or optical based disks, or a combination. Storage device(s) 884 holds code or instructions and data 886 in a persistent state (i.e., the value is retained despite interruption of power to compute platform 800). A portion of the code or instructions may comprise platform firmware that is executed on processor 810. Storage device(s) 884 can be generically considered to be a “memory,” although memory 830 is typically the executing or operating memory to provide instructions to processor 810. Whereas storage device(s) 884 is nonvolatile, memory 830 can include volatile memory (i.e., the value or state of the data is indeterminate if power is interrupted to compute platform 800). In one example, storage subsystem 880 includes controller 882 to interface with storage device(s) 884. In one example controller 882 is a physical part of interface 814 or processor 810 or can include circuits or logic in both processor 810 and interface 814.

Compute platform 800 may include an optional Baseboard Management Controller (BMC) 890 that is configured to effect the operations and logic corresponding to the flowcharts disclosed herein. BMC 890 may include a microcontroller or other type of processing element such as a processor core, engine or micro-engine, that is used to execute instructions to effect functionality performed by the BMC. Optionally, another management component (standalone or comprising embedded logic that is part of another component) may be used.

Power source 802 provides power to the components of compute platform 800. More specifically, power source 802 typically interfaces to one or multiple power supplies 804 in compute platform 800 to provide power to the components of compute platform 800. In one example, power supply 804 includes an AC to DC (alternating current to direct current) adapter to plug into a wall outlet. Such AC power can be renewable energy (e.g., solar power) power source 802. In one example, power source 802 includes a DC power source, such as an external AC to DC converter. In one example, power source 802 can include an internal battery or fuel cell source.

Various types of memory may be used in the LP memory and DDR memory modules described and illustrated herein, in a similar manner as described with reference to system 700 in FIG. 7.

As discussed above, in some embodiment the silicon chips illustrated herein may comprise Other Processing Units (collectively termed XPUs). Examples of XPUs include one or more of Graphic Processor Units (GPUs) or General Purpose GPUs (GP-GPUs), Tensor Processing Units (TPUs), Data Processing Units (DPUs), Infrastructure Processing Units (IPUs), Artificial Intelligence (AI) processors or AI inference units and/or other accelerators, FPGAs and/or other programmable logic (used for compute purposes), etc. While some of the diagrams herein show the use of CPUs, this is merely exemplary and non-limiting. Generally, any type of XPU may be used in place of a CPU in the illustrated embodiments. Moreover, as used in the following claims, the term “processor” is used to generically cover CPUs and various forms of XPUs.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

It is noted that the views, block diagrams and the like in the drawings are illustrative and not drawn to scale. For example, the relative dimensions and placements for some of the components in the views and block diagrams herein are exaggerated for clarity and point of illustration. For example, one having skill in the art will recognize the components in an actual implementation will generally have dimensions and thicknesses that are different than that shown in the Figures herein (e.g., substantially smaller and/or thinner), or be placed in a manner that is different from what is represented in a block diagram or other illustration.

It is further noted that the flow diagrams as illustrated herein provide examples of sequences of various process actions. The flow diagrams can indicate operations to be executed by a software or firmware routine, as well as physical operations. For example, in one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the invention. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein, a list of items joined by the term “at least one of” can mean any combination of the listed terms. For example, the phrase “at least one of A, B or C” can mean A; B; C; A and B; A and C; B and C; or A, B and C.

Additional example implementations are as follows:

Example 1 is a method, system, apparatus or computer-readable medium in which an embodiment of dynamic switch for memory devices comprises a memory controller, dynamic random access memory (DRAM) devices, including active and inactive DRAM devices, I/O (input/output) circuitry including an interface to a command bus including a control signal, switch circuitry to control access to the DRAM devices based on the control signal, including to provide access to the active DRAM devices and to prevent access to the inactive DRAM devices, and wherein the memory controller is to trigger the switch circuitry to switch between the active and inactive DRAM devices based on the control signal.

Example 2 is the method, system, apparatus or computer-readable medium of Example 1, wherein to trigger the switch circuitry to switch between the active and inactive DRAM devices, the memory controller is to toggle the control signal, wherein the control signal is a chip select signal.

Example 3 is the method, system, apparatus or computer-readable medium of any of Examples 1 and 2, wherein to prevent access to the inactive DRAM devices, the switch circuitry is to electrically isolate the inactive DRAM devices.

Example 4 is the method, system, apparatus or computer-readable medium of any of Examples 1, 2 and 3, wherein the DRAM devices include any of double data rate (DDR) memory device, including DDR5, DDR6, low power (LP) DDR5, and LP DDR6 memory devices.

Example 5 is the method, system, apparatus or computer-readable medium of any of Examples 1, 2, 3 and 4, wherein the DRAM devices include any of solder-down random access memory (RAM) devices located on a motherboard and DRAM devices located in a memory module, including double data rate (DDR) compression attached memory modules (CAMM), low power (LP) DDR CAMM, unbuffered dual in-line memory modules (UDIMM) and small outline DIMM (SODIMM).

Example 6 is the method, system, apparatus or computer-readable medium of any of Examples 1, 2, 3, 4 and 5, wherein the pair of memory modules include any of a top-mounted memory module and a bottom-mounted memory module, side-by-side memory modules and stacked memory modules.

Example 7 is the method, system, apparatus or computer-readable medium of any of Examples 1, 2, 3, 4, 5 and 6, wherein the switch circuitry includes one or more field effect transistor (FET) pairs to control access to the DRAM devices, including FET pairs within a memory module and FET pairs not within any memory module.

Example 8 is the method, system, apparatus or computer-readable medium of any of Examples 1, 2, 3, 4, 5, 6 and 7, wherein an FET pair comprises a metal oxide semiconductor (MOS), the MOS including any one of an n-channel MOS (NMOS), a p-channel MOS (PMOS), and a complementary MOS (CMOS).

Example 9 is the method, system, apparatus or computer-readable medium of any of Examples 1, 2, 3, 4, 5, 6, 7 and 8, wherein an FET pair corresponds to a pair of signals received in the DRAM devices, the pair of signals including data (DQ) signals, one pair of differential strobe (DQS) signals and one pair of write clock (WCK) signals.

Example 10 is a method, system, apparatus or computer-readable medium in which an embodiment of dynamic switch for memory devices comprises memory device circuitry, including a switch circuitry to control access to two memory devices, an input command bus to receive a control signal to trigger the switch circuitry to toggle access to the two memory devices and wherein, to toggle access, the switch circuitry to electrically isolate one of the two memory devices to prevent access to an isolated memory device.

Example 11 is the method, system, apparatus or computer-readable medium of Example 10, wherein the switch circuitry is co-located with the two memory devices, including on any of a motherboard and a memory module on which the two memory devices are located.

Example 12 is the method, system, apparatus or computer-readable medium of any of Examples 10 and 11, wherein the switch circuitry includes a field-effect transistor (FET) pair driven by the control signal, the FET pair comprising a metal-oxide semiconductor (MOS), including any one of an n-channel MOS (NMOS), a p-channel MOS (PMOS), and a complementary MOS (CMOS).

Example 13 is the method, system, apparatus or computer-readable medium of any of Examples 10, 11 and 12, wherein the FET pair corresponds to a pair of signals for the two memory devices, the pair of signals including any of a pair of data (DQ) signals, one pair of differential strobe (DQS) signals and one pair of write clock (WCK) signals.

Example 14 is the method, system, apparatus or computer-readable medium of any of Examples 10, 11, 12 and 13, wherein the two memory devices include any of DRAM devices, including include solder-down random access memory (RAM) devices and DRAM devices, the DRAM devices further including any of double data rate (DDR) memory devices, including DDR5, DDR6, low power (LP) DDR5, and LP DDR6 memory devices and memory modules of DRAM devices, the memory modules including any of double data rate (DDR) compression attached memory modules (CAMM), low power (LP) DDR CAMM, unbuffered dual in-line memory modules (UDIMM) and small outline DIMM (SODIMM).

Example 15 is the method, system, apparatus or computer-readable medium of any of Examples 10, 11, 12, 13 and 14, wherein the control signal is a chip select signal.

Example 16 is a method, system, apparatus or computer-readable medium in which an embodiment of dynamic switch for memory devices comprises a memory device including DRAM devices, a memory bus to receive a control signal and a switch circuit to toggle access to one of two DRAM devices at a time responsive to receipt of the control signal, and wherein a capacity of the DRAM devices is greater than an ability of the memory bus to access the two DRAM devices simultaneously.

Example 17 is a method, system, apparatus or computer-readable medium of Example 16, wherein the DRAM devices include any of solder-down random access memory (RAM) devices and DRAM devices, the DRAM devices further including any of double data rate (DDR) memory devices, including DDR5, DDR6, low power (LP) DDR5, and LP DDR6 memory devices, and memory modules of DRAM devices, the memory modules including any of double data rate (DDR) compression attached memory modules (CAMM), low power (LP) DDR CAMM, unbuffered dual in-line memory modules (UDIMM) and small outline DIMM (SODIMM).

Example 18 is a method, system, apparatus or computer-readable medium of any of Examples 16 and 17, wherein the control signal is a chip select signal.

Example 19 is a method, system, apparatus or computer-readable medium of any of Examples 16, 17 and 18, wherein the switch circuit includes a field-effect transistor (FET) pair driven by the control signal, the FET pair comprising a metal-oxide semiconductor (MOS), including any one of an n-channel MOS (NMOS), a p-channel MOS (PMOS), and a complementary MOS (CMOS).

Example 20 is a method, system, apparatus or computer-readable medium of any of Examples 16, 17, 18 and 19, wherein the FET pair corresponds to a pair of signals for the two DRAM devices, the pair of signals including any of a pair of data (DQ) signals, one pair of differential strobe (DQS) signals and one pair of write clock (WCK) signals.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. A system comprising:
a memory controller;
dynamic random access memory (DRAM) devices, including active and inactive DRAM devices; and
I/O (input/output) circuitry including an interface to a command bus including a control signal;
switch circuitry to control access to the DRAM devices based on the control signal, including to provide access to the active DRAM devices and to prevent access to the inactive DRAM devices; and
wherein the memory controller is to trigger the switch circuitry to switch between the active and inactive DRAM devices based on the control signal.

2. The system of claim 1, wherein to trigger the switch circuitry to switch between the active and inactive DRAM devices, the memory controller is to toggle the control signal, wherein the control signal is a chip select signal.

3. The system of claim 1, wherein to prevent access to the inactive DRAM devices, the switch circuitry is to electrically isolate the inactive DRAM devices.

4. The system of claim 1, wherein the DRAM devices include any of double data rate (DDR) memory device, including DDR5, DDR6, low power (LP) DDR5, and LP DDR6 memory devices.

5. The system of claim 1, wherein the DRAM devices include any of:
solder-down random access memory (RAM) devices located on a motherboard; and
DRAM devices located in a memory module, including double data rate (DDR) compression attached memory modules (CAMM), low power (LP) DDR CAMM, unbuffered dual in-line memory modules (UDIMM) and small outline DIMM (SODIMM).

6. The system of claim 5, wherein the pair of memory modules include any of:
a top-mounted memory module and a bottom-mounted memory module;
side-by-side memory modules; and
stacked memory modules.

7. The system of claim 5, wherein the switch circuitry includes one or more field effect transistor (FET) pairs to control access to the DRAM devices, including FET pairs within a memory module and FET pairs not within any memory module.

8. The system of claim 7, wherein an FET pair comprises a metal oxide semiconductor (MOS), the MOS including any one of an n-channel MOS (NMOS), a p-channel MOS (PMOS), and a complementary MOS (CMOS).

9. The system of claim 7, wherein an FET pair corresponds to a pair of signals received in the DRAM devices, the pair of signals including data (DQ) signals, one pair of differential strobe (DQS) signals and one pair of write clock (WCK) signals.

10. Memory device circuitry, comprising:
a switch circuitry to control access to two memory devices;
an input command bus to receive a control signal to trigger the switch circuitry to toggle access to the two memory devices; and
wherein, to toggle access, the switch circuitry to electrically isolate one of the two memory devices to prevent access to an isolated memory device.

11. The memory device circuitry of claim 10, wherein the switch circuitry is co-located with the two memory devices, including on any of a motherboard and a memory module on which the two memory devices are located.

12. The memory device circuitry of claim 10, wherein the switch circuitry includes a field-effect transistor (FET) pair driven by the control signal, the FET pair comprising a metal-oxide semiconductor (MOS), including any one of an n-channel MOS (NMOS), a p-channel MOS (PMOS), and a complementary MOS (CMOS).

13. The memory device circuitry of claim 12, wherein the FET pair corresponds to a pair of signals for the two memory devices, the pair of signals including any of a pair of data (DQ) signals, one pair of differential strobe (DQS) signals and one pair of write clock (WCK) signals.

14. The memory device circuitry of claim 11, wherein the two memory devices include any of:
DRAM devices, including include solder-down random access memory (RAM) devices and DRAM devices, the DRAM devices further including any of double data rate (DDR) memory devices, including DDR5, DDR6, low power (LP) DDR5, and LP DDR6 memory devices; and
memory modules of DRAM devices, the memory modules including any of double data rate (DDR) compression attached memory modules (CAMM), low power (LP) DDR CAMM, unbuffered dual in-line memory modules (UDIMM) and small outline DIMM (SODIMM).

15. The memory device circuitry of claim 11, wherein the control signal is a chip select signal.

16. A memory device comprising:
DRAM devices;
a memory bus to receive a control signal; and
a switch circuit to toggle access to one of two DRAM devices at a time responsive to receipt of the control signal; and
wherein a capacity of the DRAM devices is greater than an ability of the memory bus to access the two DRAM devices simultaneously.

17. The memory device of claim 16, wherein the DRAM devices include:
any of solder-down random access memory (RAM) devices and DRAM devices, the DRAM devices further including any of double data rate (DDR) memory devices, including DDR5, DDR6, low power (LP) DDR5, and LP DDR6 memory devices; and
memory modules of DRAM devices, the memory modules including any of double data rate (DDR) compression attached memory modules (CAMM), low power (LP) DDR CAMM, unbuffered dual in-line memory modules (UDIMM) and small outline DIMM (SODIMM).

18. The memory device of claim 16, wherein the control signal is a chip select signal.

19. The memory device of claim 16, wherein the switch circuit includes a field-effect transistor (FET) pair driven by the control signal, the FET pair comprising a metal-oxide semiconductor (MOS), including any one of an n-channel MOS (NMOS), a p-channel MOS (PMOS), and a complementary MOS (CMOS).

20. The memory device of claim 19, wherein the FET pair corresponds to a pair of signals for the two DRAM devices, the pair of signals including any of a pair of data (DQ) signals, one pair of differential strobe (DQS) signals and one pair of write clock (WCK) signals.
